(19) United States
(12) Patent Application Publication
(10) Pub. No.: US 2005/0149827 A1
(43) Pub. Date: Jul. 7, 2005

(54) Data storage apparatus and method for handling a data storage apparatus

(76) Inventors: Nicolaas Lambert, Eindhoven (NL); Ozcan Mesut, Eindhoven (NL); Rudi Jozef Marie Wijnands, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/502,142

(22) PCT Filed: Dec. 20, 2002
(86) PCT No.: PCT/IB02/05689

(30) Foreign Application Priority Data
Jan. 24, 2002 (EP) 02075289.5

(51) Int. Cl. G11C 29/00

(52) U.S. Cl. 714/770

(57) ABSTRACT

Real-time audio video applications require guaranteed request service times from a hard disc drive. This requirement is not always fulfilled due to some unexpected delays in service times. One of the causes of such delay is the replacement of defective or bad sectors. By putting spare sectors on each track and extending the track skew in combination with read-and-write-on-arrival strategies it is possible to prevent extra delays in service times due to replacement of sectors.

The invention regards a data storage apparatus comprising a data storage medium formatted in a pre-determined architecture comprising a plurality of at least one format feature, and having a user area and a spare area defined thereon. Further the invention regards a method for handling a data storage apparatus comprising a data storage medium formatted in a pre-determined architecture having a plurality of format features, and having a user area and a spare area defined thereon, wherein upon a data request of a host a controller provides at least one format feature of the data and wherein the medium is rotated and a head is moved and actuated to access the format feature to transfer data therewith.

Hard disc based devices recording e. g. multimedia streams like MPEG-encoded video require real-time file system for writing the data to a disc and for reading the data back. Real-time file systems try to write all files in time but sometimes cannot succeed for example because of disc problems. Conventionally there are then two options: writing the data too late, or discarding some of the unwritten data. The first option will typically cause buffer overflows for recording, which may lead to a significant data loss. The second option may also result in a data loss. Traditional data oriented operating systems have no real-time requirements and attend to aim for a maximum data integrity, delaying completion of each command until properly executed.

In particular real-time audio video applications require guaranteed request service times from a hard disc drive. This requirement is not always fulfilled due to some unexpected delays in service time. Replaced sectors i. e. data of defect sectors allocated to remote spare areas on a disc are one of the reasons for such delays. The delays mainly result from searching replaced sectors and from accessing the remote spare area the defect sector data have been allocated to. Such remote spare area conventionally is located in a track or tracks other than the originally accessed track of the defect sector. Therefore, track switching as well as seek time causes such delay.

In the U.S. Pat. No. 6,101,619 a scheme is provided to reduce the number of searches by accessing replaced sectors at preferably later times subsequent to a usual data access. In the U.S. Pat. No. 5,166,936 or the WO 98/03970 low level formatting of tracks is suggested to build good tracks of data to prevent a further access of a defect. Such measures take considerable effort and may only be done in idle time. Moreover such transaction system should be guarded against power failures. Spare areas are conventionally provided as remote spare areas in form of spare area tracks as for example disclosed in the U.S. Pat. No. 6,201,655 and the U.S. Pat. No. 5,822,142.

These schemes still require for a track switch and therefore, still are not able to guarantee a request service time in case of an access to a defective region or a block that contains defect, replaced or allocated sectors.

To compensate for the time needed by a read/write-head to switch track for accessing sequential data, corresponding sectors of each two adjacent tracks may be skewed i. e. corresponding sectors of each two adjacent tracks are mutually shifted in the circumferental direction. This allows a read/write-head of a disc drive to essentially arrive directly at a first sector of an adjacent track after a track switch. Such first sector may also be referred to as a start sector in the following.

According to the U.S. Pat. No. 5,568,606 a skew is provided to a multiple disc stack in order to synchronise the phase of rotation of the discs in the multiple disc system upon accessed defects occurring in the synchronisation zone on the disc. Such method may prevent performance losses of a multiple disc system due to the need of extra rotations of one disc upon the occurrence of an accessed effect.

However still such a scheme is not able to guarantee a request service time as outlined above.

This is where the invention comes in, the object of which is to specify a data storage apparatus comprising a data storage medium, in particular a disc drive comprising a data storage disc adapted such that a request service time can be guaranteed even in case of an access to a region of the storage medium that contains defective or replaced sectors. A further object of the invention is to specify a method for handling a data storage apparatus comprising a data storage medium by which a request service time may be guaranteed even in case of an access to a region of the storage medium containing defective or replaced sectors.

The object regarding the apparatus is solved by a data storage apparatus comprising a data storage medium, in particular a disc drive comprising a data storage disc, formatted in a pre-determined format architecture comprising a plurality of at least one format feature having a user area and a spare area defined thereon, wherein according to the invention the format architecture provides a plurality of spare area arrays, wherein each of the spare area arrays is respectively assigned to essentially each of the plurality of the at least one format feature.

Advantageously the apparatus may further comprise a read/write-head, a drive to rotate the disc and a servo to move the head.

It was realised, that even if data originally scheduled to a defect region are allocated or replaced or re-mapped to a remote spare region on a track or several tracks other than the originally accessed track of the defect, this may cause significant performance losses. Therefore, it is the main idea to provide essentially in each of a format feature of a disc, in particular in essentially each track at least one spare area array. This has the advantage that, if a defect should be accessed, data related to a defect may be transferred to the spare area array in the same format feature, in particular in the same track. Therefore, a switch of the format feature, in particular a switch of a track, is unnecessary to allocate the data related to the defect into a remote spare area.

Continued developed configurations are further outlined in the dependent apparatus claims.

Any number of spare sectors may be provided and can be selected dependent on the data storage medium and its format architecture. The number may be selected according to the particular use of a disc drive. At least one spare sector should be provided per track. Five spare sectors per track seems to be a reasonable number. The number may also range up to one hundred. The number should be selected considering the total number of sectors per format feature and/or data storage medium and/or storage capacity of one sector.

The number of spare sectors may depend on the format feature, they are assigned to. In general the number of spare sectors is chosen so that on the one hand upon detection of a defect the data space of the spare sectors is large enough to receive all data related to a defect. On the other hand the data space of the spare sectors may not be selected too large as this only would enlarge the spare area, however reduce the free user area available for user applications.

In a preferred continued developed configuration the format feature provides a skew for two adjacent tracks. In particular a skew for each two adjacent tracks is preferred. Such skew is a mutual shift in place of corresponding sectors of two adjacent tracks in circumferential direction. Advantageously sectors of an outer track are shifted circumferentially in the direction of rotation of the disc relative to corresponding sectors of an inner track. In particular it is preferred that the shift comprises at least the minimum number of sectors passed during a track switch upon rotation of the disc and/or a number of spare sectors comprised by a spare area array assigned to a respective track. Such development allows a spare area to be passed beyond a read/write-head at least once before a track switch, in particular once per rotation of the medium. Upon a suitable setting of this skew it may be achieved that the spare area array is passed beyond the head at least once after a track switch, in particular essentially first after a track switch. The advantage of this is, that not only start sectors may be available for a read/write-process right at the beginning of the track by the read/write-head, but also a number of spare sectors is available. In particular a conventional skew is set according to the effective time a read/write head needs to switch from one track to an adjacent track and settle on the adjacent track. The skew of the continued development of the apparatus is extended and set to account for the size of the spare area and the effective time a read/write-head needs to switch from one track to an adjacent track and settle on the adjacent track.

The skew may be extended by a number of sectors of one to ten. In particular the format architecture advantageously provides a parameter for the skew in correlation with the size of the spare area array. The total skew should be large enough to account for settle time of the head and the number of spare sectors. Also the skew should be as small as possible to avoid significant performance loss.

In a further preferred continued developed configuration the data storage apparatus proposed comprises a controller having a control electronics, a microprocessor and a memory. In particular the memory comprises a buffer memory adapted for intermediate storing of data. Moreover the controller is adapted to record the intermediate storing. Further an interface for connecting the storage apparatus to a host is provided. This development allows a read/write-head to transfer data immediately on arrival on a format feature, in particular on a track of a data storage disc. Such data may be stored in a buffer memory, the storing being recorded by the controller and subsequent upon completion of the data transfer the data storage in the buffer memory may be transferred to a host by an interface in correct logical order. A logical order of data may not be accounted for by immediate data transfer on arrival. However the read-out of the buffer memory can be performed that way according to the records of the controller. Advantageously the development saves rotational latency time as a data transfer may take place independent of the logical order of the data.

Further the invention leads to a method for handling a data storage apparatus, in particular to a data storage apparatus as described. Such data storage apparatus comprises a data storage medium formatted in predetermined architecture having a plurality of format features and having a user area and a spare area defined thereon, wherein upon a data request of a host a controller provides at least one format feature of the data, in particular at least a track and a sector, and wherein the medium is rotated and the head is moved and actuated to access the format feature to transfer data therewith. The above object regarding the method is solved by such method, wherein according to the invention each of the spare area arrays is respectively assigned to essentially each of the format features such that a spare area is passed beyond the head at least once before a track switch.

Continued developed configurations are further outlined in the dependent method claims.

In particular the format feature is selected from the group consisting of: zones, cylinders, tracks and blocks, in particular a track. Advantageously a spare area is passed beyond the head at least once after a track switch, in particular essentially first after a track switch. Preferably the spare area array is passed beyond the head at least once per rotation of the medium.

In a preferred configuration the data are transferred as soon as the head is positioned on the format feature, in particular the track, determined by the controller. In still a further preferred configuration of the invention the data are sequentially transferred and are intermediately stored in sequential order in a buffer memory and the data transfer is recorded by a controller and subsequent the data are read-out from the buffer memory and are transmitted to the host in logical order.

The invention will now be described with reference to the accompanying drawing. The figures of the drawing illustrate in a schematic and not necessarily scaled form preferred embodiments of the invention compared to prior art. The figures illustrate in:

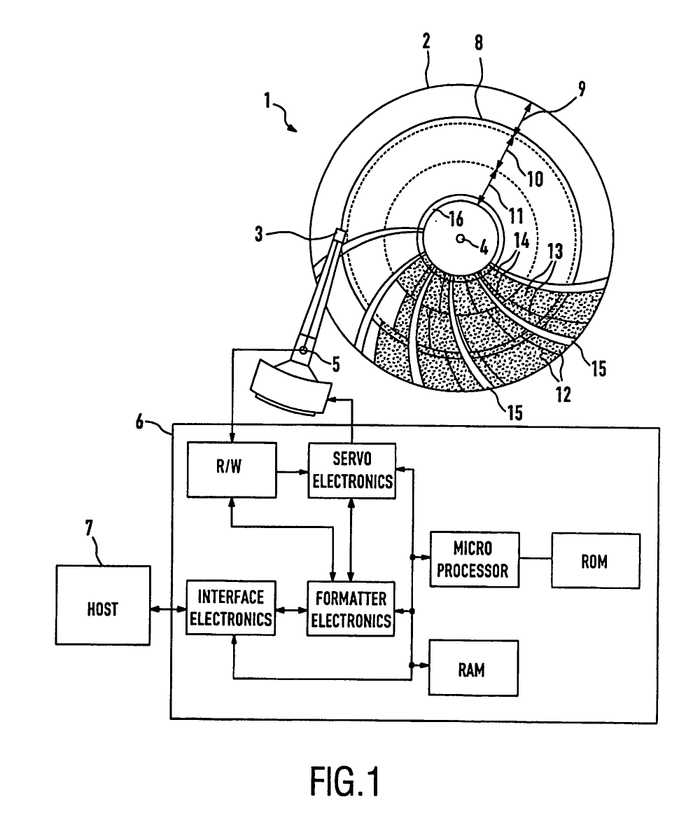

FIG. 1: a hard disc drive of prior art;

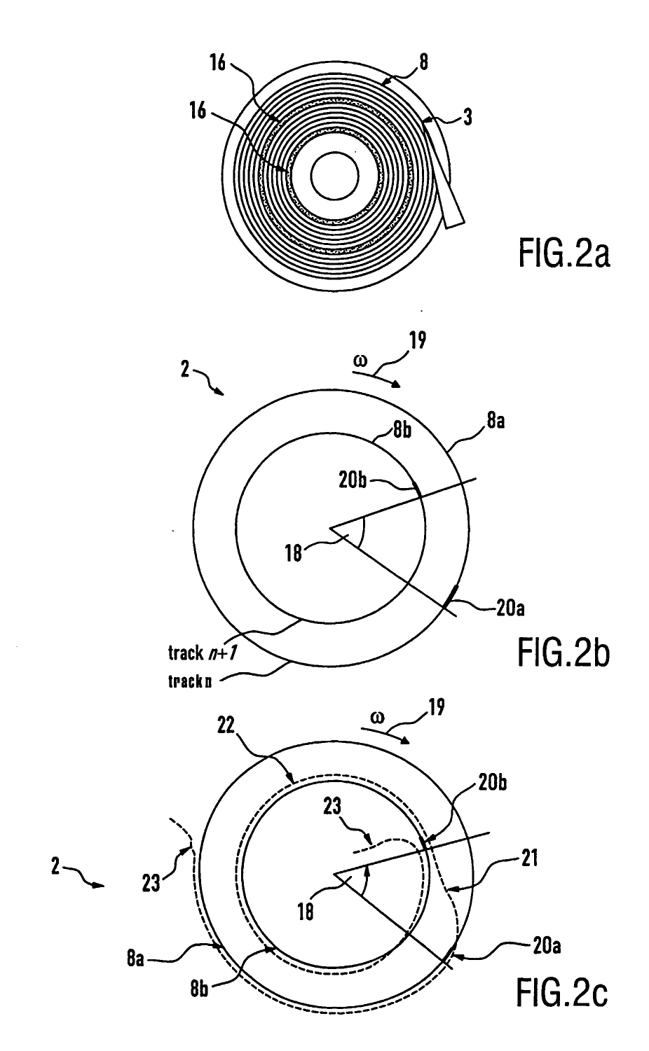

FIG. 2a: a hard disc drive of prior art with remote spare areas;

FIG. 2b: a hard disc drive of prior art with conventional skew;

FIG. 2c: a hard disc drive of prior art with conventional skew and indicated motion a read/write-head during a track switch;

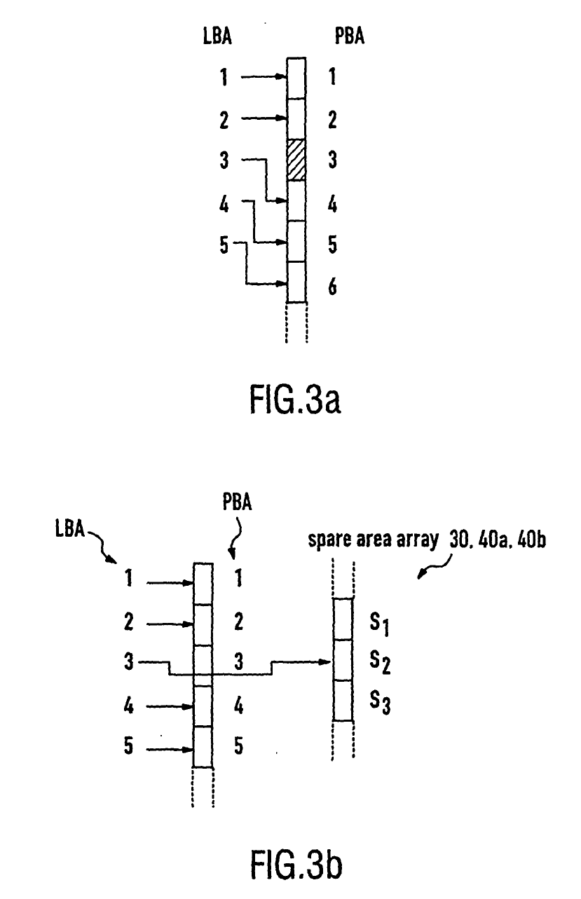

FIG. 3a: a scheme of sector skipping and slipping in the preferred embodiment;

FIG. 3b: an allocation and mapping scheme for a defective sector due to a grown defect into a spare area in the preferred embodiment;

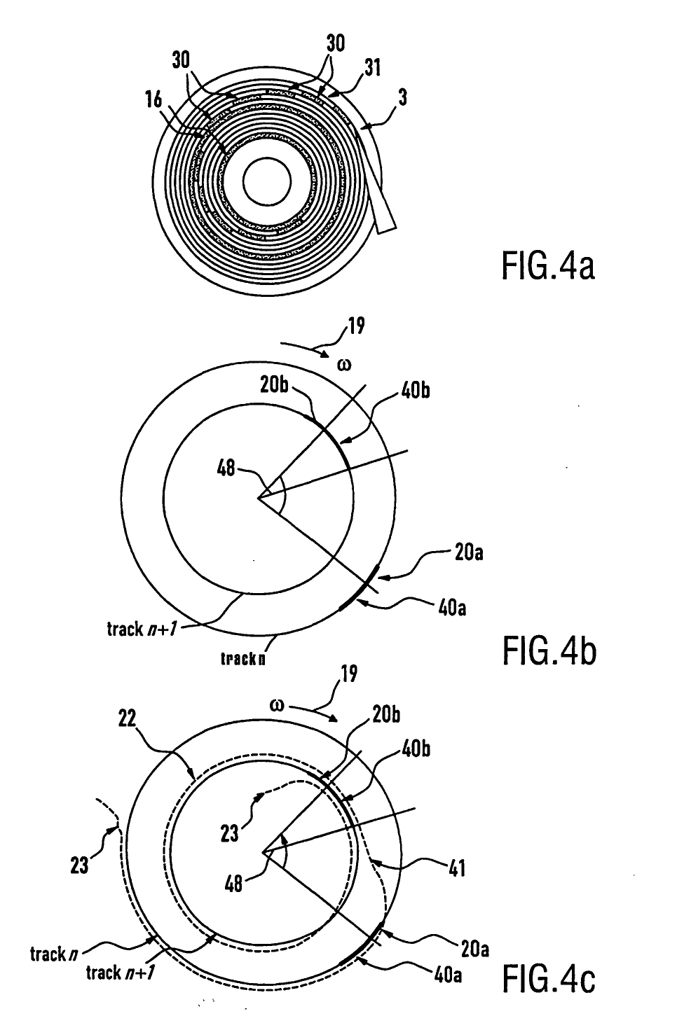

FIG. 4a: a non-remote allocation of spare sectors being part of spare area arrays on a hard disc drive in a preferred embodiment;

FIG. 4b: an extended skew on a hard disc drive taking into account spare area arrays on each track according to a preferred embodiment;

FIG. 4c: an extended skew on a hard disc drive taking into account spare area arrays on each track and indicated motion of a read/write-head during track switch according to a preferred embodiment;

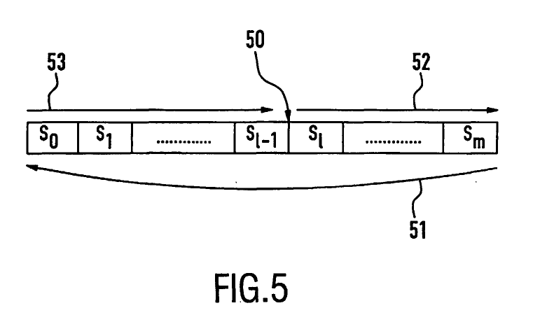

FIG. 5: an example for a scheme providing data transfer on arrival using a buffer memory according to a further preferred embodiment.

FIG. 1 illustrates the structure of a hard disc drive 1 comprising a data storage disc 2, a read/write-head 3, a drive, which is not shown, to rotate the data storage disc 2 around a spindle 4 and a servo, which is not shown, to turn the head 3 around an axis 5 to move the head 3 to a pre-determined position on the disc 2 to transfer data therewith. The head 3 is controlled by a read-and-write electronics and a servo electronics being part of the controller 6 of the disc drive. The controller 6 further comprises a formatter electronics which upon a data request converts such request into corresponding numbers of format features of the disc 2. Such data request may be received from a host 7 by an interface and an interface electronics. Further the controller 6 comprises a microprocessor, ROM and RAM e. g. a buffer memory.

The disc 2 contains according to a format architecture a plurality of format features of the kind selected from the group of zones 9, 10, 11 each comprising a plurality of tracks 8. A track is divided into a plurality of blocks 12, 13, 14. Preferably all blocks 12, 13 and 14 have the same size of data capacity. As the number of blocks per track may vary from to track to track or zone to zone some of the blocks may be divided by servo wedges 15. Servo wedges may also be evenly spaced radially around the disc like spokes on a wheel. If the disc drive 1 should contain multiple heads 3 for multiple discs 2 then the tracks 8 of a disc 2 and the corresponding tracks 8 of the further discs being at the same radius are referred to as a cylinder. In this case each track assigns a respective cylinder. Further in a conventional drive a remote spare area 16 is provided on the disc 2 as a track or plurality of tracks at the inner circumference of the disc 2.

The number, size and allocation of remote spare areas 16 may be different for different hard disc drives depending on the manufacturer and product family. For instance there can be a number of remote spare areas 16 evenly spaced in the address space as indicated in FIG. 2a. Also there may be just one remote spare area 16 located at the inner diameter, outside the user addressable area as shown in FIG. 1.

Each data storage apparatus and in particular disc drive may have dependent on its structure and handling a maximum service time. The maximum service time of a drive is the total time of the data transfer and the maximum access time and can be calculated using the formula T=AX+B. The parameter A is the transfer time of a single sector expressed in time per sector. The parameter X is the number of sectors to be transferred and the parameter B is the maximum access time which is the sum of seek time and rotational latency time. Rotational latency time may in particular but not only result when the read/write-head has to switch to a next track. In the preferred embodiment of the invention the latter may be advantageously restricted to one full rotation.

There are cases where a conventional drive is not able to finish a request within this maximum service time. Examples of such cases are retries due to an error correction code error, servo errors due to shocks and vibrations and hard errors. Hard errors are caused by media defects and are handled conventionally by the defect management of a drive. When an error correction code error cannot be corrected with several retries it is possibly caused by a media defect. To verify that the error was caused by a media defect, the drive performs a media test on each defective sector. The media test consists of write/read verifies, wherein the suspicious sectors are written and read several times. If any of them fails then the sector is a grown defect and is conventionally allocated to a remote spare sector. Defects that occur in the field are referred to as grown defects in the following.

FIG. 2a shows a schematic view of a data storage disc with a head 3 and a plurality of tracks 8 containing two remote spare areas 16.

FIG. 2b illustrates schematically a conventional track skew of an outer track 8a adjacent to an inner track 8b upon an angle 18 in circumferental direction in the direction of rotation 19 of the disc 2. Corresponding start sectors of the tracks 8a and 8b are depicted as 20a and 20b. As shown in FIG. 2b a track skew may be employed in hard disc drives to minimise rotational latency time that results when the drive has to switch to a next track to access sequential data. This is depicted by the motion 21 of the head 3 in FIG. 2c. Conventionally a skew is large enough to make sure the head 3 has enough time on the next track 8b to settle.

Track skewing provides a mutual shift of corresponding sectors in adjacent tracks in a circumferental direction relative to each other. Due to track skewing e. g. corresponding sectors of tracks are not localized in radial direction along a straight line but instead along bended lines 17 such as depicted in FIG. 1.

Further in FIG. 2c reference mark 22 depicts a read/write-operation and 23 a seek operation. To prevent seek operations during sequential data transfers it is advantageous to prevent defective sectors to be reallocated to remote spare areas.

Conventionally only during manufacturing defective sectors are skipped.

In a preferred embodiment as shown in FIG. 3a a defective sector 3 occurred during use of the data storage apparatus, known as a grown defect, may be replaced by a next immediate spare sector in order to maintain the sequential ordering of logical data sequences. This technique eliminates the need to seek to another track to access a replacement of an sector allocated in a remote spare area. If defects, known as grown defects, occur during application of a hard disc drive, such skip and slip scheme is applied during an application, i.e. in the field, in the preferred embodiment. It is applicable within a wide and unlimited range, as a spare area may be provided for essentially each of a plurality of at least one format feature, in particular a track. Conventionally defects that occur during application are, if found, allocated to a remote spare sector at another track.

In the situation depicted in FIG. 3b, the physical sector PBA 3 is allocated to the replacement sector S2 in a spare area array on the same track. Therefore such spare area array is not a remote spare area. The logical address LBA 3 is mapped to the replacement sector S2 in the spare area array on the same track. Converting the physical sector PBA 3 into a slipped sector in the field, is indicated in FIG. 3a. This allows in the field for not only a shift in the logical to physical address mapping but also for a shift of a content of the corresponding sectors. In the example of FIG. 3b this means that the logical block address LBA 3 will be mapped on the physical block address PBA 4, LBA 4 will be mapped on PBA 5, LBA 5 will be mapped on PBA 6 and so on.

In a further development at the same time the content of PBA 3 which is located at the replacement sector S2 on the same track can be moved from S2 to PBA 4 and the content of PBA 4 has to be moved to PBA 5 and so on. This slipping in the field should continue until a free sector e. g. a spare sector of the spare area of the same track is reached. Otherwise, a discontinuity in the logical to physical mapping exists as it is the case e. g. when a sector is allocated to a remote replacement sector on another track.

Conventionally the allocation process of a defective sector causes an extra delay in service time of a disc drive. When the drive 1 encounters a defective sector and decides to allocate it to a remote spare area 16, the head 3 is moved from the track 8 with the defective sector in the user area to a track 8 where spare sectors are allocated in a remote spare area 16. When the right spare sector is rotated under the read/write-head 3, the data is written to the spare sector. Subsequent, if the drive has to resume reading or writing, the head is moved back to the original track 8 where the defective sector was found. This process costs extra time due to searching and accessing the sector allocated in the remote spare area 16: the head 3 has to move to the spare sector in a remote spare area 16 to read or write at the spare sector and the head 3 has to move back to track 8 to resume reading or writing. In a real-time audio-video application therefore, conventional methods for handling data and a conventional data storage apparatus may not guarantee a maximum service time in case an error occurs. Alternatively delivering erroneous or incomplete data to the host 7 and reporting the error has to be taken into account. When accessing a data pool with one or more erroneous sectors, the drive will also be unable to finish the request within the maximum service time.

The embodiment illustrated in FIG. 4a provides spare sectors 30 on each track 31 to prevent a seek action to a remote spare sector. Doing so guarantees maximum service time even in cases, in which a defect sector is accessed. When requested data are located on one track and within track boundaries, they can be transferred within one disc revolution, even if it contains re-allocated sectors as long as the number of re-allocated sectors does not exceed the number of spares 30 on the track 31. A multiple number of complete tracks can also be transferred within the maximum service time, even if each track contains a limited number of re-allocated sectors in the spare area 30 of each track according to the preferred embodiment.

In a further preferred embodiment the track skew is improved. For instance when a requested pool of data lies across track boundaries and is not a multiple number of complete tracks and is not aligned with physical tracks and contains replaced sectors on the last track, it cannot be transferred by conventional methods within the maximum service time. Specifically if one is to transfer two consecutive sectors lying on consecutive tracks, e. g. the last sector of track n and the first sector of track n+1 depicted in FIG. 4b, under the assumption that the first sector of track n+1 is defect and is allocated to a spare sector located at the end of the track, in the worst case one has to wait one full rotation to access the sector on track n. After the head is switched to the next track one has to wait another full rotation to access the replaced sector. In this case the service time exceeds the maximum service time by almost one full rotation, i. e. to be precise, one full rotation minus the transfer time of one sector.

Such performance can be solved if the spare sectors are accessed first after a track switch. As shown in FIG. 4b and by the motion 41 of the read/write-head 3 in FIG. 4c the problem can be solved by extending the conventional track skew 18 according to the preferred embodiment to an extended track skew 48. The extension is adapted such that the spare sectors 40b are always accessed first after a track switch 41 and the spare sectors 40a are always accessed before a track switch 41. As illustrated by the motion 41 of the read/write-head 3 spare sectors 40a are always accessed before a track switch 41 in order to guarantee maximum service time when the pool of requested data starts in the middle of a track n. Further the spare sectors 40b also are accessed after a track switch 41, preferably first after a track switch 41, to guarantee maximum service time for a requested pool of data which ends at the middle of a track n+1. In general the spare sectors 30, 40a, 40b in FIGS. 4a, 4b and 4c are at least accessed once per revolution of a disc 2. Thereby, the maximum service time is guaranteed even when access to a replaced sector has to be made. This scheme is successful as long as the number of defective sectors does not exceed the number of spare sectors 30 allocated on each track 31. Therefore, the number of spare sectors may be suitable set on demand.

A further continued developed embodiment prevents extra delays in the service time by applying a read-and-write-on-arrival strategy as indicated in FIG. 5. Such strategy is also referred to as transfer-on-arrival strategy or zero-latency-read or out-of-order-read strategy. This developed embodiment allows a drive 1 according to a preferred embodiment to start reading and writing data as soon as possible after the read/write-head 3 is positioned on the right requested track. If on arrival the last part of the requested data is passing under the head 3, then this part of the data is read into a drive's buffer first e. g. RAM or ROM. This is referred to in FIG. 5 by 52 with regard to the sectors S₁ to Sₘ following the seek position 50. Upon further rotation 51 of the disc 2 under the head 3 the remaining part of the data in sectors S₀ to S₁₋₁ following the start sector of the respective track are read into the drive buffer as the disc 2 rotates under the head 3. This is referred to by 53 in FIG. 5.When requested data are stored in the drive's buffer, the requested data are transferred from the drive's buffer to the host, preferably in sequential order.

Similar to the described read-on-arrival strategy is the write-on-arrival strategy. The data do not have to be written to the disc 2 in the right order. Once the data is in the drive's buffer e. g. RAM or ROM the last part of the data may by written to the disc 2 first and then the remaining part of the data.

Read-and-write-on-arrival strategies, i. e. transfer-on-arrival strategies, reduce the rotational latency time for disc accesses. In conventional methods for handling data a seek is required for the access. The conventional read strategy provides that the drive waits for a start sector of a requested data pool to pass under the head 3 once the head 3 is positioned on the right track. This causes substantial performance losses.

Therefore, the advantage of the read-and-write-on-arrival strategy as a development of the preferred embodiment, is that the maximum service time is shorter than the conventional maximum service time.

In particular this is a achieved when the transfer length Sₒ to Sₘ is shorter than a track and no track boundaries are crossed. In such a case the maximum service time with transfer-on-arrival strategy is specifically a seek time plus one disc revolution. This is assigned by the parameter B being the maximum access time which is the sum of seek time and rotational latency time. Data transfer may be provided parallel to the data access.

In comparison in a conventional strategy the maximum service time will always be described by the formula AX+B, i. e. the transfer time plus seek time plus at most one disc revolution.

When a request block lies across track boundaries or is not a multiple number of complete tracks or is not aligned with physical tracks and contains replaced sectors on the last track, such a problem is solved by applying extending the track skew 48 such that these spare sectors 40a, 40b are always accessed first after a track switch and always accessed before a track switch. This way the maximum service time is guaranteed when accessing re-allocated sectors as long as the number of defective sectors does not exceed the number of spare sectors 30, 40a, 40b allocated on each track 31.

Further the combination of the outlined strategy of spare sectors 30, 40a, 40b on each track and extended track skew 48 may be combined with read-and-write-on-arrivals strategies of FIG. 5 to establish a very efficient tool to guarantee maximum service times.

In particular the number of spare sectors 30, 40a, 40b to be allocated on each track, as spare sectors in a spare area array per track 31 depends on the number of sectors per track, the grown defect statistics of a drive and how much drive capacity can be sacrificed. Current hard disc drives have about five hundred sectors per track on average. Putting five spare sectors on each track means 1% decrease in capacity. Such slight decrease is acceptable and may even be extended to 2% or 3%. Moreover, a decrease in number of sectors per track due to spare sectors and extended skew time results in a slight decrease in data throughput of a drive. However such decrease in sustained data rate of a drive is clearly less than 2%, so that the minimum data transfer time may be slightly raised.

For example a hard disc drive may be rotated with 5400 rotations per minute, providing 500 sectors per track and 3 ms track skew corresponding to a rotation time of 11.2 ms and a sustained data transfer rate of 17.19 MB/s. The sustained data transfer rate is determined according to the formula:

$$data transfer rate = \frac{sector per track}{rotation time + skew}$$

Preferably five spare sectors on each track may be suitable, so that the track skew should be extended by 112 μs, which corresponds to the rotation time of five sectors. So the extended track skew 48 has become 3.112 ms and the number of sectors per track 495. The corresponding sustained data rate is 16.89 MB/s which corresponds to a 1.77% decrease in the sustained data transfer rate of the drive.

Such reduced data transfer rates and address capacity is only a negligible sacrifice in view of the fact that the allocation strategy as proposed guarantees maximum request service time even when replaced sectors must be accessed by the drive to execute the request. It opens possibilities to separate media-test for suspicious sectors from the replacement process, or to turn replaced sectors into slipped sectors for example when a sector must be replaced to a spare sector on another track, because the spares on the same track are used up.

While there has been shown and described what is considered to be preferred embodiments of the invention, it will of course be understood that various modifications and changes in form or detail could readily be made without departing from the spirit of the invention. It is therefore intended that the invention may not be limited to the exact form and detail herein shown and described nor to anything less than the whole of the invention herein disclosed and as herein after claimed.

The invention may be summarised as follows:

Real-time audio video applications require guaranteed request service times from a hard disc drive. This requirement is not always fulfilled due to some unexpected delays in service times. One of the causes of such delay is the replacement of defective or bad sectors. By putting spare sectors on each track and extending the track skew in combination with read-and-write-on-arrival strategies it is possible to prevent extra delays in service times due to replacement of sectors.

1. Data storage apparatus (1) comprising a data storage medium (2), in particular a disc drive (1) comprising a data storage disc (2), formatted in a pre-determined format architecture comprising a plurality of at least one format feature (8, 9, 10, 11, 12, 13, 14), and having a user area and a spare area defined thereon, characterised in that the format architecture provides a plurality of spare area arrays (30, 40a, 40b) wherein each of the spare area arrays (30, 40a, 40b) is respectively assigned to essentially each of the plurality of the at least one format feature (8, 9, 10, 11, 12, 13, 14).

2. Data storage apparatus as claimed in claim 1, characterised in that essentially each of a plurality of tracks (8) comprises at least one spare area array (30, 40a, 40b).

3. Data storage apparatus as claimed in claim 1, wherein a spare area array (30, 40a, 40b) comprises at least one and up to one hundred spare sectors, in particular up to ten, advantageously five spare sectors per track.

4. Data storage apparatus as claimed in claim 1, characterised in that the format architecture provides a skew (18, 48) for two adjacent tracks (n, n+1) being a mutual shift in place of corresponding sectors of two adjacent tracks (n, n+1) in circumferental direction (19).

5. Data storage apparatus as claimed in claim 4, characterised in that sectors of an outer track (n) are shifted circumferencally in the direction of rotation of the disc relative to corresponding sectors of an inner track (n+1), wherein in particular the shift comprises at least the minimum number of sectors passed during a track switch upon rotation (19) of the disc and/or a number of spare sectors (40a, 40b) comprised by a spare area array assigned to a respective track.

6. Data storage apparatus as claimed in claim 4, characterised in that a skew is extended by a number of sectors of one to ten.

7. Data storage apparatus as claimed in claim 4, characterised in that the format architecture provides a parameter to set the skew (48) in correlation with the size of the spare area array (30, 40a, 40b).

8. Data storage apparatus (1) as claimed in claim 1, characterised in that a controller (6) having a control electronics, a microprocessor and a memory is provided wherein a buffer memory (RAM, ROM) is adapted for intermediate storing of data and the controller (6) is adapted to record the intermediate storing, wherein further an interface for connecting the storage apparatus to a host (7) is provided.

9. Method for handling a data storage apparatus (1), in particular a data storage apparatus (1) according to claim 1, comprising a data storage medium (2) formatted in a pre-determined architecture having a plurality of format features, and having a user area and a spare area defined thereon, wherein upon a data request of a host a controller (6) provides at least one format feature of the data, in particular at least a track and a sector, and wherein the medium (2) is rotated (19) and a head (3) is moved and actuated to access the format feature to transfer data therewith, characterised in that the format architecture provides a plurality of spare area arrays (30, 40a, 40b), wherein each of the spare area arrays (30, 40a, 40b) is respectively assigned to essentially each of the format features such that a spare area (30, 40a, 40b) is passed beyond the head (3) at least once before a track switch (41).

10. Method as claimed in claim 9, characterised in that the format feature is selected from the group consisting of: zones (9, 10, 11), cylinders (8), tracks (8) and blocks (12, 13, 14).

11. Method as claimed in claim 9, characterised in that a spare area array (30, 40a, 40b) is passed beyond the head (3) at least once after a track switch (41), in particular essentially first after a track switch (41).

12. Method as claimed in claim 9, characterised in that the spare area array (30, 40a, 40b) is passed beyond the head (3) at least once per rotation (19) of the medium (2).

13. Method as claimed in claim 9, characterised in that data are transferred as soon as the head (3) is positioned on the format feature, in particular track (8), determined by the controller (6).

14. Method as claimed in claim 13, characterised in that the data are sequentially transferred and are intermediately stored in sequential order in a buffer memory (RAM, ROM) and the data transfer is recorded by a controller (6) and subsequent the data are read out from the buffer memory (RAM, ROM) and are transmitted to the host (7) in logical order.
